(19) United States
(12) Patent Application Publication
(10) Pub. No.: US 2013/0078455 A1
(43) Pub. Date: Mar. 28, 2013

(54) Metal-Aluminum Alloy Films From Metal PCAI Precursors And Aluminum Precursors

(71) Applicants: David Thompson, San Jose, CA (US); Jeffrey W. Anthis, San Jose, CA (US)

(72) Inventors: David Thompson, San Jose, CA (US); Jeffrey W. Anthis, San Jose, CA (US)

(73) Assignee: Applied Materials, Inc., Santa Clara, CA (US)

(21) Appl. No.: 13/617,082

(22) Filed: Sep. 14, 2012

Related U.S. Application Data
(60) Provisional application No. 61/538,628, filed on Sep. 23, 2011.

(51) Int. Cl. C23C 16/20; B32B 15/20; C23C 16/36; C22C 21/00; C23C 16/32; C23C 16/34

(52) U.S. Cl. 428/336; 427/250; 427/249.17; 427/248.1; 420/528

(57) ABSTRACT

Described are methods for deposition of metal-aluminum films using metal PCAI precursors and aluminum precursors. Such metal-aluminum films can include metal aluminum carbide, metal aluminum nitride and metal aluminum carbonitride films. The aluminum precursors may be alkyl aluminum precursors or amine alanes.

### CROSS-REFERENCE TO RELATED APPLICATIONS

This application claims the benefit under 35 U.S.C. §119(e) to U.S. Provisional Application No. 61/538,628, filed Sep. 23, 2011, the entire content of which is incorporated herein by reference in its entirety.

### TECHNICAL FIELD

The present invention relates generally to methods of depositing thin films of metal-aluminum alloys and to films deposited using such methods. In particular, the invention relates to deposition of metal-aluminum, metal aluminum carbide, metal aluminum nitride and metal aluminum carbonitride films.

### BACKGROUND

Deposition of thin films on a substrate surface is an important process in a variety of industries including semiconductor processing, diffusion barrier coatings and dielectrics for magnetic read/write heads. In the semiconductor industry, in particular, miniaturization requires atomic level control of thin film deposition to produce conformal coatings on high aspect structures. One method for deposition of thin films with atomic layer control and conformal deposition is atomic layer deposition (ALD), which employs sequential, self-limiting surface reactions to form layers of precise thickness controlled at the Ångstrom or monolayer level. Most ALD processes are based on binary reaction sequences which deposit a binary compound film. Each of the two surface reactions occurs sequentially, and because they are self-limiting, a thin film can be deposited with atomic level control. Because the surface reactions are sequential, the two gas phase reactants are not in contact, and possible gas phase reactions that may form and deposit particles are limited. The self-limiting nature of the surface reactions also allows the reaction to be driven to completion during every reaction cycle, resulting in films that are continuous and pinhole-free.

ALD has been used to deposit metals and metal compounds on substrate surfaces. Al₂O₃ deposition is an example of a typical ALD process illustrating the sequential and self-limiting reactions characteristic of ALD. Al₂O₃ ALD conventionally uses trimethylaluminum (TMA, often referred to as reaction “A” or the “A” precursor) and H₂O (often referred to as the “B” reaction or the “B” precursor). In step A of the binary reaction, hydroxyl surface species react with vapor phase TMA to produce surface-bound AlOAl(CH₃)₂ and CH₄ in the gas phase. This reaction is self-limited by the number of reactive sites on the surface. In step B of the binary reaction, AlCH₃ of the surface-bound compound reacts with vapor phase H₂O to produce AlOH bound to the surface and CH₄ in the gas phase. This reaction is self-limited by the finite number of available reactive sites on surface-bound AlOAl(CH₃)₂. Subsequent cycles of A and B, purging gas phase reaction products and unreacted vapor phase precursors between reactions and between reaction cycles, produces Al₂O₃ growth in an essentially linear fashion to obtain the desired film thickness.

While perfectly saturated monolayers are often desired, this goal is very difficult to achieve in practice. The typical approach to further ALD development has been to determine whether or not currently available chemistries are suitable for ALD. Although a few processes have been developed that are effective for deposition of certain transition metal-aluminum layers using transition metal halides and alkyl aluminum precursors, in general ALD processes for deposition of meta-aluminum layers have not been sufficiently successful to be adopted commercially. There is a need for new deposition chemistries that are commercially viable with a wide range of metals. The present invention addresses this problem by providing novel precursor combinations which are specifically designed and optimized to take advantage of the atomic layer deposition process.

### SUMMARY

One aspect of the invention pertains to a method of depositing a metal-aluminum layer, the method comprising exposing a substrate surface to pulses of a metal PCAI precursor and an aluminum precursor to form a metal-aluminum layer on the substrate surface, wherein the metal PCAI precursor comprises a p or f-block metal and the aluminum precursor comprises an alkyl aluminum precursor or an amine alane. In various embodiments, the substrate surface is not exposed to an oxidant during formation of the metal-aluminum layer.

In one or more embodiments of this aspect, the metal-aluminum layer comprises a metal aluminum carbide layer, a metal aluminum nitride layer, or a metal aluminum carbonitride layer. In some embodiments, the metal-aluminum layer comprises less than 5, 4, 3, 2, 1, 0.5, 0.25, 0.1, 0.05 or 0.01 weight % oxygen.

In a further embodiment, the metal aluminum-layer comprises metal aluminum carbide. In certain embodiments of this aspect, the substrate is heated to a temperature of about 100° C. to about 500° C.

According to one or more embodiments, the substrate surface is exposed to the pulses sequentially, simultaneously, or substantially simultaneously. In some embodiments, the deposition process is an atomic layer deposition process.

In one or more embodiments, the metal PCAI precursor has a structure represented by:

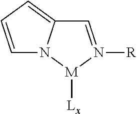

wherein R is a C₁₋₆ straight or branched alkyl, M is a p or f-block metal, Lₓ are x ligands, x is a number from 1-4, and with each L independently being the same or different ligand as another L. In some embodiments, one or more Ls is a PCAI ligand. In a further embodiment, the metal in the metal PCAI precursor comprises lanthanum.

One or more embodiments of this aspect use an alkyl aluminum precursor has a structure represented by:

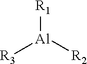

wherein R₁, R₂ and R₃ are each independently hydrogen or a C₁-C₈ straight or branched alkyl. In one embodiment, R₁, R₂ and R₃ are the same. In other embodiments, the alkyl aluminum precursor comprises one or more of trimethyl aluminum, triethyl aluminum and dimethylaluminumhydride. According to some embodiments, the alkyl aluminum precursor comprises trimethyl aluminum.

In one or more embodiments, the aluminum precursor is an amine alane. The amine alane may be alane coordinated to a tertiary amine. In some embodiments, the tertiary amine has a molecular weight less than 250 g/mol.

According to one or more embodiments, the deposition process further comprises exposing the substrate surface to a second metal PCAI precursor comprising a second p or f-block metal. In some embodiments, the second metal PCAI precursor comprises an f-block metal.

Another aspect of the invention pertains to a method of depositing a metal-aluminum layer by atomic layer deposition, the method comprising sequentially exposing a substrate surface to alternating pulses of a metal PCAI precursor and an aluminum precursor to form a metal-aluminum layer on the substrate surface. According to one or more embodiments of this aspect, the substrate surface is not exposed to an oxidant during formation of the metal-aluminum layer. In some embodiments, the metal-aluminum layer is oxide-free.

In one or more embodiments of this aspect, the metal PCAI precursor has a structure represented by:

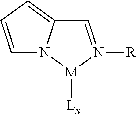

wherein R is a C₁₋₆ straight or branched alkyl, M is p or f-block metal, Lₓ are x ligands, x is a number from 1-4, and with each L independently being the same or different ligand as another L. In some embodiments, M is an f-block metal.

According to one or more embodiments, the aluminum precursor is an alkyl aluminum precursor has a structure represented by:

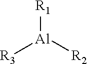

wherein R₁, R₂ and R₃ are each independently hydrogen or a C₁-C₈ straight or branched alkyl.

In one or more embodiments, the aluminum precursor is an amine alane. The amine alane may be alane coordinated to a tertiary amine. In some embodiments, the tertiary amine has a molecular weight less than 250 g/mol.

In some embodiments of this aspect, the metal-aluminum layer comprises a metal aluminum carbide layer, a metal aluminum nitride layer, or a metal aluminum carbonitride layer. In a further embodiment, the metal aluminum-layer comprises metal aluminum carbide. According to one or more embodiments, the substrate is heated to a temperature of about 100° C. to about 500° C.

In further embodiments, the metal in the metal PCAI precursor comprises lanthanum.

In one or more embodiments, the alkyl aluminum precursor comprises one or more of trimethyl aluminum, triethyl aluminum and dimethylaluminum-hydride. In some embodiments, the alkyl aluminum precursor comprises trimethyl aluminum.

Yet another aspect of the invention pertains to a method of depositing a lanthanum-aluminum layer by atomic layer deposition, the method comprising sequentially exposing a surface of a substrate to alternating pulses of lanthanum PCAI precursor and trimethyl aluminum to form on the surface a lanthanum-aluminum layer. In some embodiments, the lanthanum-aluminum layer comprises lanthanum aluminum carbide. In one or more embodiments, the substrate is heated to a temperature of about 100° C. to about 500° C.

Another aspect of the present invention pertains to a metal-aluminum layer deposited by one of the methods described herein. In one or more embodiments, metal-aluminum layer has a thickness in the range from about 1 to about 10 nm. In some embodiments, the metal-aluminum layer is less than 5 weight % oxygen.

### DETAILED DESCRIPTION

Before describing several exemplary embodiments of the invention, it is to be understood that the invention is not limited to the details of construction or process steps set forth in the following description. The invention is capable of other embodiments and of being practiced or being carried out in various ways. It is also to be understood that the complexes and ligands of the present invention may be illustrated herein using structural formulas which have a particular stereochemistry. These illustrations are intended as examples only and are not to be construed as limiting the disclosed structure to any particular stereochemistry. Rather, the illustrated structures are intended to encompass all such complexes and ligands having the indicated chemical formula.

Reference throughout this specification to “one embodiment,” “certain embodiments,” “one or more embodiments” or “an embodiment” means that a particular feature, structure, material, or characteristic described in connection with the embodiment is included in at least one embodiment of the invention. Thus, the appearances of the phrases such as “in one or more embodiments,” “in certain embodiments,” “in one embodiment” or “in an embodiment” in various places throughout this specification are not necessarily referring to the same embodiment of the invention. Furthermore, the particular features, structures, materials, or characteristics may be combined in any suitable manner in one or more embodiments.

In one or more embodiments, a film composed largely of metal and aluminum, and in some embodiments, carbon and/or nitrogen, is deposited on a substrate. Such films can have n-metal film characteristics and can be used as metal gate materials. Thus, according to one or more embodiments, the metal-aluminum film is oxide-free, as the presence of oxygen increases the dielectric constant of the film and makes it unsuitable for use as a metal gate material.

As used herein, “oxide-free” means that the oxygen content of the metal-aluminum film is below a certain tolerability threshold. In one embodiment, an “oxide-free” film is less than 5 weight % oxygen. In a further embodiment, an oxide-free film is less than 1 weight % oxygen. According to another embodiment, the oxide-free film is less than 0.1 weight % oxygen. In yet another embodiment, the oxide-free film is less than 0.01 weight % oxygen. In some embodiments, the metal-aluminum layer comprises less than 5, 4, 3, 2, 1, 0.5, 0.25, 0.1, 0.05 or 0.01 weight % oxygen.

However, in other embodiments, the film contains oxygen.

As used herein, “substantially simultaneously” refers to either co-flow or where there is merely overlap between exposures of the two components.

According to one aspect of the invention, a metal-aluminum film is deposited on a substrate surface using metal PCAI precursors and aluminum precursors. In one or more embodiments, the substrate surface is exposed to the pulses sequentially, simultaneously, or substantially simultaneously. In some embodiments, the film may be deposited by sequentially exposing the substrate surface to alternating pulses of the metal PCAI precursor and the aluminum precursor

PCAI refers to a 2-methyliminopyrrolyl ligand. Metal PCAI precursors typically have better vapor pressure than corresponding metal halide precursors. For many metals, metal chlorides do not have sufficient vapor pressure to allow delivery of the metal. Thus, use of metal PCAI precursors increases the range of metals that can be deposited through atomic layer deposition or other deposition processes.

In one embodiment, the metal PCAI precursor comprises a metal coordination complex that may be represented by formula (I):

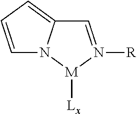

wherein R is a C₁₋₆ straight or branched alkyl. M is any p or f-block metal. Lₓ are x ligands, x is a number from 1-4, and with each L independently being the same or different ligand as another L. Lₓ can include additional PCAI ligands. In some embodiments, Lₓ does not include acetylacetonate, β-ketoiminate, β-diketiminate, amidinate, tridentate amidinate, or diazabutadiene. According to one or more embodiments, R is an isopropyl group. In some embodiments, M is an f-block metal.

In all the above ligands of formula (I), the R group substituent may be selected to control characteristics of the metal coordination complex. R may be selected to tune the sterics of the precursor. Sterics should be selected such that the precursor does not become too bulky, and the vapor pressure will drop to an unusable level for vapor deposition.

According to one or more embodiments, the metal in the metal PCAI precursor comprises lanthanum.

In addition to the metal PCAI precursor, a second precursor is used in the atomic layer deposition process. This second precursor is an aluminum precursor, which is used to supply the aluminum for the film. The aluminum can also be a carbon source if the metal-aluminum film comprises a metal aluminum carbide or metal aluminum carbonitride film. In one or more embodiments, the aluminum precursor may be an alkyl aluminum precursor or an amine alane.

According to one or more embodiments, the aluminum precursor is an alkyl aluminum precursor that may be represented by formula (II):

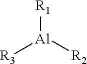

wherein R₁, R₂ and R₃ are each independently hydrogen or a C₁-C₈ straight or branched alkyl.

In one embodiment, R₁, R₂ and R₃ are the same functional group, i.e. are all hydrogen or are all the same alkyl group. In some embodiments, the alkyl aluminum precursor comprises one or more of trimethyl aluminum (TMA), triethyl aluminum (TEA) and dimethylaluminumhydride (DMAH). TMA, TEA and DMAH are all commercially-available compounds. In some embodiments, the alkyl aluminum precursor comprises trimethyl aluminum, which has the structure of formula (III):

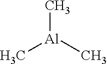

The aluminum precursor may also be an amine alane. In one or more embodiments, the amine alane is alane coordinated to a tertiary amine. In some embodiments, the amine is a tertiary amine. Some embodiments provide that the tertiary amine has a molecular weight less than or equal to 250 g/mol.

In one or more embodiments, the amine alane is represented by the structure of formula (V):

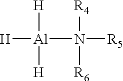

wherein R₄, R₅ and R₆ are each independently a C₁-C₈ straight or branched alkyl. In one or more embodiments, two or more of R₄, R₅ and R₆ may form a cyclic structure, such as with N-methylpyrrolidine.

According to one or more embodiments, the deposition process further comprises exposing the substrate surface to a second metal PCAI precursor comprising a second p or f-block metal. In some embodiments, the second metal PCAI precursor comprises an f-block metal. When two or more metal PCAI precursors are used, the substrate may be exposed to the two precursors sequentially, simultaneously, or substantially simultaneously.

Certain embodiments pertain to a metal-aluminum layer that comprises nitrogen, such as a metal aluminum nitride or metal aluminum carbonitride film. In such embodiments, the nitrogen incorporated into the film can originate from the PCAI ligands in the metal PCAI precursor.

Another aspect of the invent relates to a method of depositing a metal-aluminum layer by atomic layer deposition, the method comprising sequentially exposing a surface of a substrate to alternating pulses of a metal PCAI precursor and an aluminum precursor to form a metal-aluminum layer on the substrate surface. In accordance with embodiments of this aspect, the metal PCAI precursor has a structure represented by formula (I):

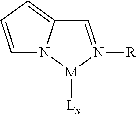

wherein R is a C₁₋₆ straight or branched alkyl. M is any p or f-block metal. Lₓ are x ligands, x is a number from 1-4, and with each L independently being the same or different ligand as another L. Lₓ can include additional PCAI ligands. In some embodiments, Lₓ does not include acetylacetonate, β-ketoiminate, β-diketiminate, amidinate, tridentate amidinate, or diazabutadiene. According to one or more embodiments, R is an isopropyl group. In some embodiments, M is an f-block metal.

The aluminum precursor in accordance with this aspect may be an alkyl aluminum precursor having a structure represented by formula (II):

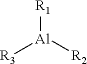

wherein R₁, R₂ and R₃ are each independently hydrogen or a C₁-C₈ straight or branched alkyl.

The aluminum precursor may also be an amine alane. In one or more embodiments, the amine alane is alane coordinated to a tertiary amine. In some embodiments, the amine is a tertiary amine. Some embodiments provide that the tertiary amine has a molecular weight less than or equal to 250 g/mol.

In one or more embodiments, the amine alane is represented by the structure of formula (V):

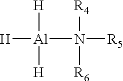

wherein R₄, R₅ and R₆ are each independently a C₁-C₈ straight or branched alkyl. In one or more embodiments, two or more of R₄, R₅ and R₆ may form a cyclic structure, such as with N-methylpyrrolidine.

In one or more embodiments, the metal-aluminum layer comprises a metal aluminum carbide layer, a metal aluminum nitride layer, or a metal aluminum carbonitride layer. In a further embodiment, the metal aluminum-layer comprises metal aluminum carbide. According to one or more embodiments, the metal-aluminum layer is oxide-free.

In one embodiment, the metal in the metal PCAI precursor comprises lanthanum.

According to one or more embodiments, the alkyl aluminum precursor comprises one or more of trimethyl aluminum, triethyl aluminum and dimethylaluminumhydride. In one or more embodiments, the alkyl aluminum precursor comprises trimethyl aluminum.

Another aspect of the invention relates to a method of depositing a lanthanum-aluminum layer by atomic layer deposition, the method comprising sequentially exposing a surface of a substrate to alternating pulses of lanthanum PCAI precursor and trimethyl aluminum to form on the surface a lanthanum-aluminum layer. In one or more embodiments, the lanthanum-aluminum layer is oxide-free. In one or more embodiments, the lanthanum-aluminum layer comprises lanthanum aluminum carbide.

The reaction conditions for the ALD reaction will be selected based on the properties of the selected ligands for the metal PCAI and the properties of the aluminum precursor. The deposition can be carried out at a reduced pressure. The vapor pressure of the metal PCAI should be low enough to be practical in such applications. The substrate temperature should be high enough to keep the bonds between the metal atoms at the surface intact and to prevent thermal decomposition of gaseous reactants. However, the substrate temperature should also be high enough to keep the source materials (i.e., the reactants) in the gaseous phase and to provide sufficient activation energy for the surface reaction. The appropriate temperature depends on the specific precursors used and the pressure. According to one or more embodiments, the substrate is heated to a temperature of about 100° C. to about 500° C.

The properties of a precursor for use in the ALD deposition methods of the invention can be evaluated using methods known in the art, allowing selection of appropriate temperature and pressure for the reaction. In general, lower molecular weight and the presence of functional groups that increase the rotational entropy of the ligand sphere result in a melting point that yields liquids at typical delivery temperatures and increased vapor pressure.

An optimized metal PCAI precursor for use in the deposition methods of the invention will have all of the requirements for sufficient vapor pressure, sufficient thermal stability at the selected substrate temperature and sufficient reactivity to produce a self-limiting reaction on the surface of the substrate without unwanted impurities in the thin film or condensation. Sufficient vapor pressure ensures that molecules of the source compound are present at the substrate surface in sufficient concentration to enable a complete self-saturating reaction. Sufficient thermal stability ensures that the source compound will not be subject to the thermal decomposition which produces impurities in the thin film.

Any metal PCAI, including but not limited to complexes represented by formula (I), and having suitable vapor pressure properties may be used in the thin layer film deposition methods of the invention.

In an exemplary embodiment of an ALD process, a first chemical precursor (“A”) is pulsed, for example, delivering a metal species containing substituents to the substrate surface in a first half reaction. A first chemical precursor “A” is selected so its metal reacts with suitable underlying species to form new self-saturating surface. Excess unused reactants and the reaction by-products are removed, typically by an evacuation-pump down and/or by a flowing inert purge gas. Then a second chemical precursor (“B”), is delivered to the surface, wherein the second chemical precursor “B” also forms self-saturating bonds with the underlying reactive species to provide another self-limiting and saturating second half reaction. A second purge period is typically utilized to remove unused reactants and the reaction by-products.

To form another layer, a second pulse of the first chemical precursor “A” is delivered to the layer from the first deposition cycle, which then reacts with the layer on the substrate surface. The deposition cycle of pulses of the A precursor, B precursor, A precursor, B precursor (typically including purges between each pulse) is then repeated used to build a metal-aluminum layer of the desired thickness. It will be understood that the “A”, “B”, and purge gases can flow simultaneously, and the substrate and/or gas flow nozzle can oscillate such that the substrate is sequentially exposed to the A, purge, and B gases as desired.

In some embodiments, the first chemical precursor “A” may be a metal PCAI precursor and the second chemical precursor “B” may be an aluminum precursor, but it is possible to begin the cycle with either precursor.

The precursors and/or reactants may be in a state of gas, plasma, vapor or other state of matter useful for a vapor deposition process. During the purge, typically an inert gas is introduced into the processing chamber to purge the reaction zone or otherwise remove any residual reactive compound or by-products from the reaction zone. Alternatively, the purge gas may flow continuously throughout the deposition process so that only the purge gas flows during a time delay between pulses of precursor and reactants.

In one or more embodiments, at least two different types of metal-containing precursors can be utilized. Thus, a “C” metal-containing precursor may be utilized, wherein the “C” metal-containing precursor is different from the “A” metal-containing precursor thereby providing ALD cycle A, B, C, B, A, B, C, B, A, B, C, B . . . (with purges in between each pulse). Likewise a different type of second reactant (a “D” reactant) may be utilized in a reaction sequence, in which “B” and “D” reactants are different to provide a reaction sequence in which the following pulsed ALD cycle is utilized A, B, C, D, A, B, C, D . . . (with purges between each pulse). As noted above, instead of pulsing the reactants, the gases can flow simultaneously from a gas delivery head or nozzle and the substrate and/or gas delivery head can be moved such that the substrate is sequentially exposed to the gases.

Of course, the aforementioned ALD cycles are merely exemplary of a wide variety of ALD process cycles in which a deposited layer is formed.

A deposition gas or a process gas as used herein refers to a single gas, multiple gases, a gas containing a plasma, combinations of gas(es) and/or plasma(s). A deposition gas may contain at least one reactive compound for a vapor deposition process. The reactive compounds may be in a state of gas, plasma, vapor, during the vapor deposition process. Also, a process may contain a purge gas or a carrier gas and not contain a reactive compound.

A “substrate surface,” as used herein, refers to any substrate or material surface formed on a substrate upon which film processing is performed during a fabrication process. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, and any other materials such as metals, metal nitrides, metal alloys, and other conductive materials, depending on the application. Barrier layers, metals or metal nitrides on a substrate surface include titanium, titanium nitride, tungsten nitride, tantalum and tantalum nitride, aluminum, copper, or any other conductor or conductive or non-conductive barrier layer useful for device fabrication. Substrates may have various dimensions, such as 200 mm or 300 mm diameter wafers, as well as, rectangular or square panes. Substrates on which embodiments of the invention may be useful include, but are not limited to semiconductor wafers, such as crystalline silicon (e.g., Si<100> or Si<111>), silicon oxide, strained silicon, silicon germanium, doped or undoped polysilicon, doped or undoped silicon wafers, III-V materials such as GaAs, GaN, InP, etc. and patterned or non-patterned wafers. Substrates may be exposed to a pretreatment process to polish, etch, reduce, oxidize, hydroxylate, anneal and/or bake the substrate surface.

The reactants are typically in vapor or gas form. The reactants may be delivered with a carrier gas. A carrier gas, a purge gas, a deposition gas, or other process gas may contain nitrogen, hydrogen, argon, neon, helium, or combinations thereof. Plasmas may be useful for depositing, forming, annealing, treating, or other processing of the materials described herein.

In one or more embodiments, the various gases for the process may be pulsed into an inlet, through a gas channel, from various holes or outlets, and into a central channel. In one or more embodiments, the deposition gases may be sequentially pulsed to and through a showerhead. Alternatively, as described above, the gases can flow simultaneously through gas supply nozzle or head and the substrate and/or the gas supply head can be moved so that the substrate is sequentially exposed to the gases.

Another aspect of the invention pertains to an apparatus for deposition of a film on a substrate to perform a process according to any of the embodiments described above. In one embodiment, the apparatus comprises a deposition chamber for CVD or ALD of a film on a substrate. The chamber comprises a process area for supporting a substrate. The apparatus include a first inlet in fluid communication with a supply of metal PCAI precursor. The apparatus further includes a second inlet in fluid communication with a purge gas. The apparatus further includes a third inlet in fluid communication with a supply of aluminum precursor. The apparatus can further include a vacuum port for removing gas from the deposition chamber. The apparatus can further include a fourth inlet for supplying one or more auxiliary gases such as inert gases to the deposition chamber. The apparatus can further include a means for heating the substrate by radiant and/or resistive heat.

Another aspect of the invention pertains to a metal-aluminum layer deposited by any of the methods described herein. In one or more embodiments, metal-aluminum layer has a thickness in the range from about 1 to about 10 nm. In some embodiments, the metal-aluminum layer is less than 5 weight % oxygen.

In one or more embodiments, the metal-aluminum layer comprises a metal aluminum carbide layer, a metal aluminum nitride layer, or a metal aluminum carbonitride layer.

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of depositing a metal-aluminum layer, the method comprising:
exposing a substrate surface to pulses of a metal PCAI precursor and an aluminum precursor to form a metal-aluminum layer on the substrate surface, wherein the metal PCAI precursor comprises a p or f-block metal and the aluminum precursor comprises an alkyl aluminum precursor or an amine alane.

2. The method of claim 1, with the proviso that the substrate surface is not exposed to an oxidant during formation of the metal-aluminum layer.

3. The method of claim 1, wherein the metal-aluminum layer is less than 5 weight % oxygen.

4. The method of claim 1, wherein the substrate surface is exposed to the pulses sequentially, simultaneously, or substantially simultaneously.

5. The method of claim 1, wherein the metal PCAI precursor comprises an f-block metal.

6. The method of claim 1, further comprising exposing the substrate surface to a second metal PCAI precursor comprising a second p or f-block metal.

7. The method of claim 1, wherein the metal-aluminum layer comprises a metal aluminum carbide layer, a metal aluminum nitride layer, or a metal aluminum carbonitride layer.

8. The method of claim 2, wherein the metal-aluminum layer comprises metal aluminum carbide.

9. The method of claim 1, wherein the substrate is heated to a temperature of about 100° C. to about 500° C.

10. The method of claim 1, wherein the metal PCAI precursor has a structure represented by: 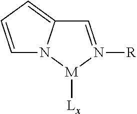
wherein R is a C₁₋₆ straight or branched alkyl, M is p or f-block metal, Lₓ are x ligands, x is a number from 1-4, and with each L independently being the same or different ligand as another L.

11. The method of claim 10, wherein the metal in the metal PCAI precursor comprises lanthanum.

12. The method of claim 1, wherein the aluminum precursor comprises an alkyl aluminum precursor having a structure represented by: 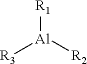
wherein R₁, R₂ and R₃ are each independently hydrogen or a C₁-C₈ straight or branched alkyl.

13. The method of claim 12, wherein R₁, R₂ and R₃ are the same.

14. The method of claim 12, wherein the alkyl aluminum precursor comprises one or more of trimethyl aluminum, triethyl aluminum and dimethylaluminumhydride.

15. The method of claim 1, wherein the aluminum precursor comprises alane coordinated to a tertiary amine having a molecular weight less than or equal to 250 g/mol.

16. A method of depositing a metal-aluminum layer by atomic layer deposition, the method comprising:
sequentially exposing a surface of a substrate to alternating pulses of a metal PCAI precursor and an aluminum precursor to form a metal-aluminum layer on the substrate surface, wherein the metal PCAI precursor has a structure represented by: 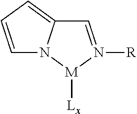
wherein R is a C₁₋₆ straight or branched alkyl, M is p or f-block metal, Lₓ are x ligands, x is a number from 1-4, and with each L independently being the same or different ligand as another L, and the aluminum precursor is an amine alane or an alkyl aluminum precursor having a structure represented by: 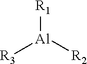
wherein R₁, R₂ and R₃ are each independently hydrogen or a C₁-C₈ straight or branched alkyl.

17. The method of claim 16, wherein the alkyl aluminum precursor comprises one or more of trimethyl aluminum, triethyl aluminum and dimethylaluminumhydride.

18. A metal-aluminum layer deposited by the method of claim 1.

19. The metal-aluminum layer of claim 18, wherein the metal-aluminum layer has a thickness in the range from about 1 to about 10 nm.

20. The metal-aluminum layer of claim 18, wherein the metal-aluminum layer is less than 5 weight % oxygen.
